(19) United States
(12) Patent Application Publication
(10) Pub. No.: US 2008/0293251 A1
(43) Pub. Date: Nov. 27, 2008

(54) METHOD FOR MANUFACTURING SEMICONDUCTOR DEVICE

(75) Inventors: Katsuaki AOKI, Kanagawa-ken (JP); Hiroshi KATSUMATA, Kanagawa-ken (JP); Keisuke UNOSAWA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/053,122

(22) Filed: Mar. 21, 2008

(30) Foreign Application Priority Data
Mar. 27, 2007 (JP) 2007-082551

(51) Int. Cl. H01L 21/3065

(52) U.S. Cl. 438/714; 257/E21.218

(57) ABSTRACT

A method for manufacturing a semiconductor device in which a first hole and a second hole having a lower aspect ratio than the first hole are formed in an insulating film formed on a semiconductor substrate is provided. The method includes: performing a first etching process configured to etch the insulating film; and performing a second etching process configured to etch the insulating film. The second etching process is performed under a condition that deposition rate of a deposited layer formed on a surface of the insulating film is lower than that in the first etching process.

### CROSS-REFERENCE TO RELATED APPLICATIONS

This application is based upon and claims the benefit of priority from the prior Japanese Patent Application No. 2007-082551, filed on Mar. 27, 2007; the entire contents of which are incorporated herein by reference.

### BACKGROUND OF THE INVENTION

1. Field of the Invention

This invention relates to a method for manufacturing a semiconductor device, and more particularly to a method for manufacturing a semiconductor device in which a hole or a groove is formed in its etching step.

2. Background Art

In manufacturing a semiconductor device, a single mask is often used to form a high-aspect-ratio hole or groove and a low-aspect-ratio hole or groove in the same substrate such as a wafer.

Conventionally, to form a fine hole in an interlayer insulating film, an etching mask is formed on the interlayer insulating film, and then the interlayer insulating film exposed through the etching mask is etched away using an etching gas containing a fluorocarbon gas, oxygen gas, and argon gas, for example, to form the hole. However, in practice, the diameter of the hole may partly increase and result in bowing, or the mask may be scraped off because the etching selection ratio of the etching mask is small. In addition, the etching mask may be kinked or locally etched due to the influence of the fluorination of the etching mask surface and the plasma ion energy. Hence the inner wall of the interlayer insulating film is roughened, causing a problem of scalloping (scallop-like roughening).

As a countermeasure thereagainst, the proportion of oxygen gas in the etching gas is decreased to reduce the etching rate. However, etch stop occurs in which a polymer layer produced by decomposition of the fluorocarbon gas is deposited and thickened, thereby stopping etching. If the thickness of the mask is small and a sufficient etching selection ratio cannot be ensured, then the first half of the etching step is performed under a condition allowing less deposition of the polymer layer, and the second half of the etching step is performed under another condition facilitating deposition of the polymer layer. Thus a desired etching shape is obtained (JP-A 2002-110647 (Kokai)).

However, in the context of downscaling, if the condition allowing less deposition of the polymer layer is used by increasing the etching rate in the first half of the etching step, the hole is spread, and the hole diameter cannot be controlled. Hence, as another method, from the first half of the etching step, etching is performed by an etching plasma source having a high ion energy while using the condition facilitating deposition of the polymer layer. However, if a low-aspect-ratio hole intended for alignment in a lithography step of the post-process is simultaneously etched from the viewpoint of improving productivity, the low-aspect-ratio hole may be etched insufficiently because a polymer layer is deposited on the hole bottom. In this case, there occurs a problem of failing to optically read the alignment mark because of the insufficient depth of the hole. In particular, the post-process includes CMP (chemical mechanical polishing) grinding for surface planarization. Hence, unless the hole is deeply etched, its step height vanishes, and the mark is difficult to read.

It is noted that a layered resist process (stacked-mask process, S-MAP) is disclosed as a method for manufacturing a semiconductor device (Toshiba Review, Vol. 59, No. 8, pp. 22-25, hereinafter referred to as Non-patent literature 1). In addition, the performance of etching using a fluorocarbon gas is disclosed (I. W. Coburn and H. F. Winters, 3. Vac. Sci. Technol. 16 (1979) 391, hereinafter referred to as Non-patent literature 2).

### SUMMARY OF THE INVENTION

According to an aspect of the invention, there is provided a method for manufacturing a semiconductor device in which a first hole and a second hole having a lower aspect ratio than the first hole are formed in an insulating film formed on a semiconductor substrate, the method including: performing a first etching process configured to etch the insulating film; and performing a second etching process configured to etch the insulating film under a condition that deposition rate of a deposited layer formed on a surface of the insulating film is lower than that in the first etching process.

According to another aspect of the invention, there is provided a method for manufacturing a semiconductor device in which a first hole and a second hole having a lower aspect ratio than the first hole are formed in an insulating film formed on a semiconductor substrate, the method including: performing a first etching process configured to etch the insulating film; and performing a second etching process configured to etch the insulating film under a condition that etching rate of the insulating film is higher than that in the first etching process.

### BRIEF DESCRIPTION OF THE DRAWINGS

FIG. 1A and FIG. 1B are schematic process cross-sectional views illustrating a method for manufacturing a semiconductor device according to an embodiment of the invention;

FIG. 2A and FIG. 2B are schematic process cross-sectional views illustrating a method for manufacturing a semiconductor device according to the embodiment of the invention;

FIG. 3 is a schematic view illustrating an etching apparatus which can conduct a method for manufacturing a semiconductor device according to the embodiment of the invention;

FIG. 4 is a table showing etching rates for an insulating film in a first etching process and a second etching process;

FIG. 5A and FIG. 5B are schematic process views illustrating the etching process for high-aspect-ratio holes according to a comparative example;

FIG. 6A and FIG. 6B are schematic process views illustrating the etching process for high-aspect-ratio holes according to the comparative example;

FIG. 7 is a table showing combinations of etching time for the first etching process and the second etching process according to the comparative example in reverse order; and

FIG. 8 is a view showing results of the diameter of the hole for the first etching process and the second etching process according to the comparative example in reverse order.

### DETAILED DESCRIPTION OF THE INVENTION

An embodiment of the invention will now be described with reference to the drawings.

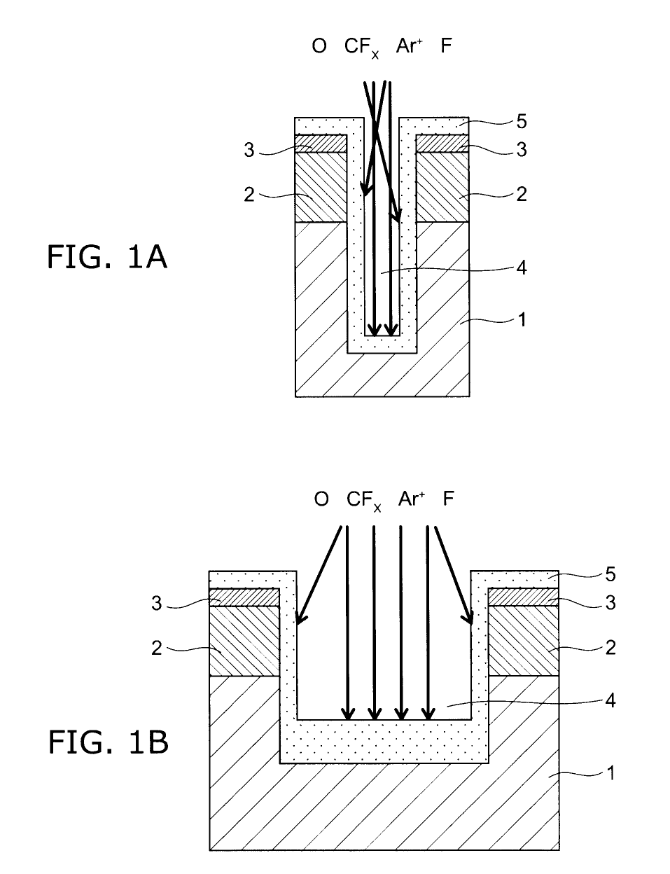

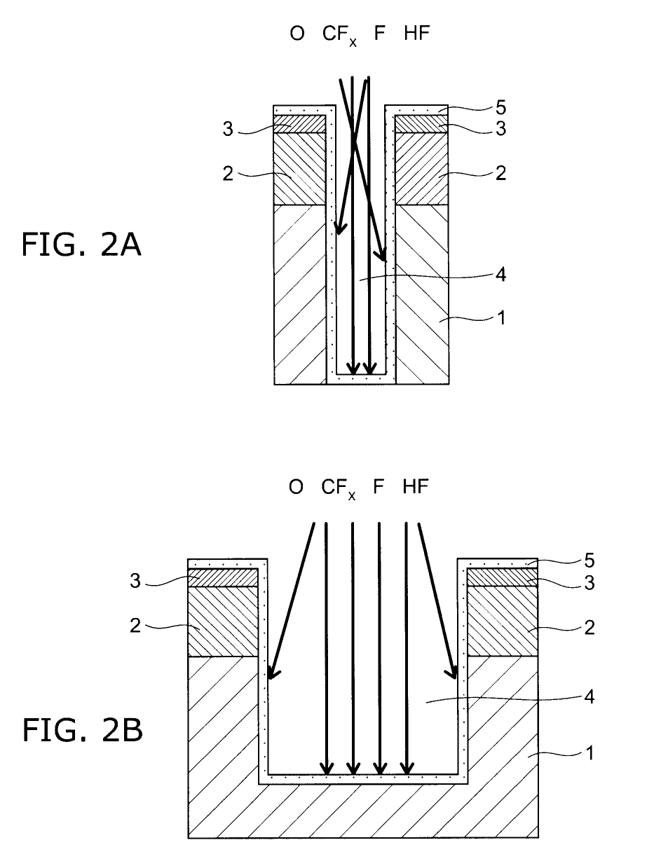

FIGS. 1 and 2 show schematic process cross-sectional views of a method for manufacturing a semiconductor device according to the embodiment of the invention.

The method for manufacturing a semiconductor device according to this embodiment includes a method for forming a high-aspect-ratio hole or groove and a low-aspect-ratio hole or groove in the same substrate such as a wafer using a single mask. This method can be based on the layered resist process (stacked-mask process, S-MAP) (Non-patent literature 1). More specifically, as shown in FIG. 1, a mask pattern 2 made of a spin-on C film and a mask pattern 3 made of a spin-on glass are formed on an insulating film 1 of silicon oxide. The mask patterns 2 and 3 are patterned in advance by a resist mask. The insulating film 1 is punctured with a hole 4 by plasma etching. Here, a high-aspect-ratio hole and a low-aspect-ratio hole are formed in the same substrate. The etching gas used is a mixed gas containing a fluorocarbon gas, oxygen, and argon.

On the surface of the insulating film 1, that is, on the inner surface of the hole 4 and the surface of the mask patterns 2 and 3, fluorine-deficient unsaturated CFₓ produced by decomposition of the fluorocarbon gas is polymerized and deposited as a polymer layer 5. The polymer layer 5 reacts with silicon oxide of the insulating film 1 upon receiving the energy of argon ions and volatilizes as SiF₄ and CO, thereby advancing etching. With the progress of etching, the plasma of the fluorocarbon gas becomes deficient in fluorine, further advancing polymerization, which dominates etching. In such an environment, a condition facilitating deposition of the polymer layer 5 is obtained. It is considered that the polymer layer 5 is made of not only CFₓ, but its mixture with SiF₄, Si, C, etc.

It is known that a fluorocarbon gas has higher etching performance as the F/C ratio increases, e.g., C₄F₈ has higher etching performance than C₄F₆, and that the etching performance increases as the oxygen gas flow rate increases (Non-patent literature 2). In addition, the etching performance decreases with the decrease of the F/C ratio or by addition of hydrogen gas.

Atomic oxygen and atomic fluorine react with CFₓ, controlling the amount of the polymer layer 5.

FIG. 1A schematically shows a process cross section of a first etching process in which a high-aspect-ratio hole is formed. The etching gas used is a mixed gas containing C₄F₆, oxygen (O₂), and argon (Ar). C₄F₆ has a low etching rate among fluorocarbon gases. Argon serves also to decelerate decomposition of CₓF_{y}. Hence, in the first etching process, etching is performed under a condition facilitating deposition of the polymer layer 5 by decreasing the flow rate of oxygen gas, which accelerates etching. In the first etching process, etching is terminated before the high-aspect-ratio fine hole reaches a prescribed hole diameter. Here, if etching is performed for a long period of time under this condition, the polymer layer 5 may become too thick with the progress of its deposition, causing etch stop.

FIG. 1B schematically shows a process cross section of the first etching process in which a low-aspect-ratio hole is formed. In a wide hole, the polymer layer 5 is excessively formed and thickly deposited on the surface of the mask patterns 2 and 3 and the inner wall of the hole 4. A hole having a low aspect ratio, which is approximately 0.1 times or less that of the high-aspect-ratio fine hole, is formed to a prescribed depth at an etching rate that is 80% or less of that for the high-aspect-ratio fine hole. As compared with the case of high aspect ratio, the polymer layer is deposited more easily, and etch stop is more likely to occur. Hence the processing time for the first etching process needs to be set to expire before the high-aspect-ratio fine hole reaches the prescribed hole diameter and before etch stop of the low-aspect-ratio hole occurs.

In the layered resist process adapted to downscaling, a resist pattern is transferred to the insulating film 1 using a spin-on glass and a spin-on C film. Hence the mask material needs to have high etching selection ratio with respect to the insulating film 1. In the first etching process, a mask material having an etching selection ratio of 3 or more is used.

FIG. 2A schematically shows a process cross section of a second etching process in which a high-aspect-ratio hole is formed to a prescribed hole diameter. The etching gas used is a mixed gas containing C₄F₈ and O₂. C₄F₈ has a high F/C ratio and high reactivity with the polymer layer 5 and silicon oxide of the insulating film 1. Hence excessive deposition of the polymer layer 5 can be avoided. Furthermore, because of the absence of argon, C₄F₈ rarely exists in the form of CₓF_{y}, but is largely decomposed to CF or CF₂ having low attachment probability. Hence the deposit decreases. It is considered that even without argon, etching proceeds with the assistance of other ions existing in the plasma. Although the etching rate increases, if formation of the polymer layer 5 is excessively suppressed, then after a long-term etching process, the mask pattern itself may be etched to result in an insufficient selection ratio, and expansion of the hole diameter or scalloping on the hole inner wall may occur during etching of the insulating film 1. However, the hole can be penetrated through the insulating film 1 under a prescribed condition.

FIG. 2B schematically shows a process cross section of the second etching process in which a low-aspect-ratio hole is formed. This process has a lower etching rate than the formation of a high-aspect-ratio hole, but causes no etch stop due to excessive deposition of the polymer layer 5. Thus it is possible to allow the high-aspect-ratio fine hole to reach a prescribed hole diameter, simultaneously with forming the low-aspect-ratio hole to a prescribed depth. Furthermore, the hole can be also penetrated through the insulating film 1 under a prescribed condition.

Conventionally, high-rate etching (with little deposition) is performed before low-rate etching (with much deposition). However, if C₄F₆ or the like is used for forming a high-aspect-ratio hole, its deposition begins with the beginning of low-rate etching (with much deposition), preventing the progress of etching. Furthermore, for high-aspect-ratio etching in the context of downscaling, etching with little deposition performed at the beginning causes a problem of insufficient control of lateral etching of the hole, failing to control the size of the hole.

In contrast, in this embodiment, at the beginning, a high-aspect-ratio hole is etched so that its shape is adjusted to a small hole dimension, while a low-aspect-ratio hole is also etched to some extent. Subsequently, by high-rate etching, the shape of the high-aspect-ratio hole is adjusted, and simultaneously, the wide hole can be etched together with the deposit to a desired shape and depth.

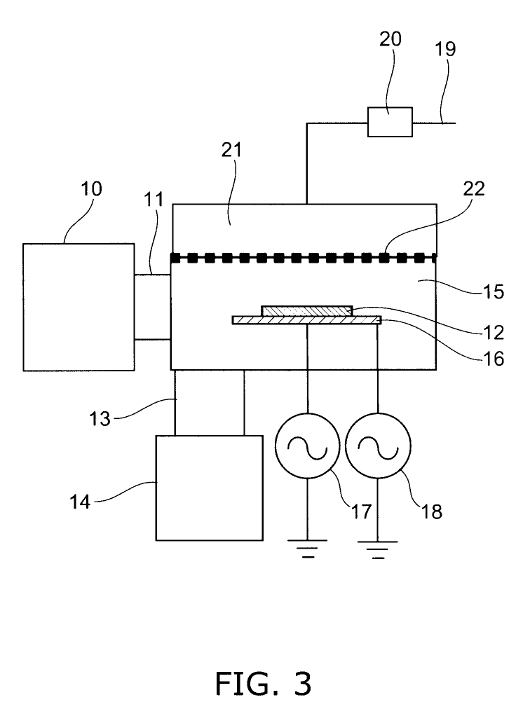

FIG. 3 is a schematic view of an etching apparatus.

A semiconductor substrate 12 transported from a transport chamber 10 through a gate valve 11 is passed through a gate valve 13 and mounted on a lower electrode 16 provided in a processing chamber 15 connected to a vacuum pump 14. A 100-MHz high-frequency power supply 17 and a 3.2-MHz high-frequency power supply 18 are used to apply high-frequency radiation. The gas needed for processing is supplied from a gas supply apparatus 19, not shown, through a gas flow regulator 20 to a gas supply chamber 21, and supplied through through holes 22 to the processing chamber 15.

An etching process that was performed using the above apparatus is described in detail in contrast to a comparative example.

In the same substrate, a high-aspect-ratio hole having a short diameter of 80 nanometers, a long diameter of 400 nanometers, and a depth of 420 nanometers was formed simultaneously with hole formation of a groove-shaped alignment mark measuring 2 microns wide and 26 microns long.

As a typical etching condition for the first etching process, for example, the pressure was 20 mTorr, the 100-MHz high-frequency electromagnetic wave power was 500 W, the 3.2-MHz high-frequency electromagnetic wave power was 400 W, the C₄F₆ flow rate was 35 sccm, the Ar flow rate was 400 sccm, the O₂ flow rate was 28 sccm, and the etching time was 71 seconds. As a typical etching condition for the second etching process, for example, the pressure was 20 mTorr, the 100-MHz high-frequency electromagnetic wave power was 1500 W, the 3.2-MHz high-frequency electromagnetic wave power was 2500 W, the C₄F₈ flow rate was 60 sccm, the CH₂F₂ flow rate was 12 sccm, the CO flow rate was 600 sccm, the O₂ flow rate was 18 sccm, and the etching time was 36 seconds.

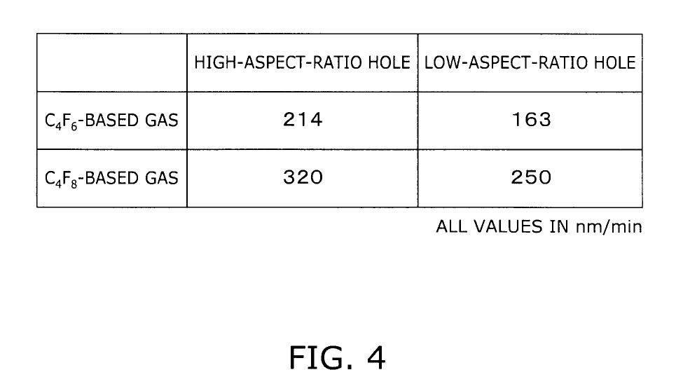

FIG. 4 is a table showing etching rates for the high-aspect-ratio and low-aspect-ratio hole in the first etching process based on C₄F₆ and the second etching process based on C₄F₈.

In the first etching process, the etching rates for the high-aspect-ratio and low-aspect-ratio hole were 214 nanometers per minute and 163 nanometers per minute, respectively. In the second etching process, they were 320 nanometers per minute and 250 nanometers per minute, respectively. It is found that the etching rate is higher in the etching process based on C₄F₈.

In the first etching process, the high-aspect-ratio hole was etched to a depth of 253 nanometers as specified, and the low-aspect-ratio groove was etched to a depth of 192 nanometers.

In the high-aspect-ratio hole, no expansion of the hole diameter or etch stop was not found in planar and cross-sectional observations of the hole by SEM (scanning electron microscopy).

Also in the low-aspect-ratio hole, no etch stop due to excessive deposition of the polymer layer 5 occurs at this stage. By observation using an optical microscope, formation of the alignment mark is recognized. However, because of insufficient processing depth, optical reading is impossible at this stage. By SEM observation in a cross section across the groove of the alignment mark, formation of the groove is confirmed.

Next, the second etching process is described in detail.

At the beginning of the second etching process, as described above, the depth of the groove of the low-aspect-ratio alignment mark was 192 nanometers, which is insufficient for optical reading. However, when plasma etching using a C₄F₈-based gas was continuously performed for 36 seconds, the groove was formed to a depth of approximately 340 nanometers, being optically readable. Processing to a prescribed depth is also confirmed by cross-sectional SEM observation. In the high-aspect-ratio hole, after etching for approximately 36 seconds, it is confirmed from planar and cross-sectional observations by SEM that the hole is formed in the insulating film 1 without bending of the C film of the mask pattern 2.

Etching was further continued for approximately 70 seconds. Then, in the high-aspect-ratio hole, bending of the C film of the mask pattern 2, indicating a preliminary stage of scalloping, started to occur. However, the hole shape was not disturbed, and no scalloping occurred.

Because of the increased F/C ratio of the etching gas, the etching rate increased, but the O₂ flow rate itself decreased. The decrease of O₂ flow rate has an effect of decreasing the etching rate. However, it is considered that the effect was compensated for by other components of the mixed gas.

For example, CH₂F₂ is decomposed in the plasma to produce HF. It is considered that HF contributes to increasing the etching rate because of its high reactivity with silicon oxide.

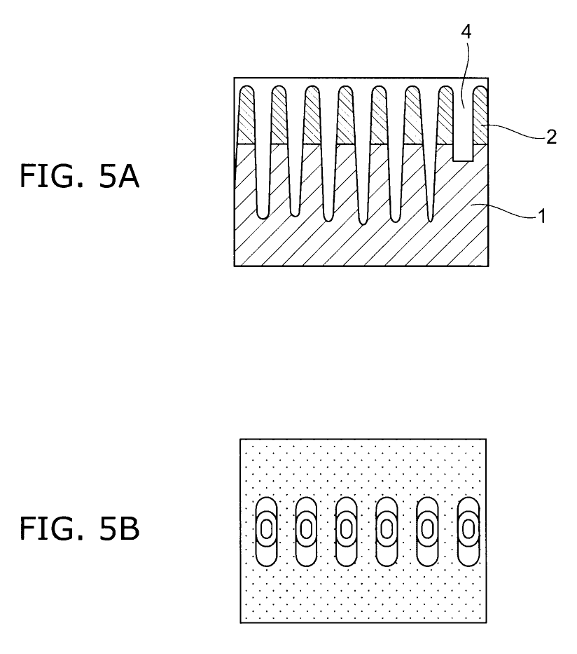

As a comparative example, FIGS. 5A and 5B show structures of high-aspect-ratio holes formed by long-term etching under the condition for the first etching process.

Because of the condition facilitating deposition of the polymer layer 5, etch stop occurs in some of the holes. In the cross-sectional structure shown in FIG. 5A, the boundary between the C film of the mask pattern 2 and the insulating film 1 is clearly confirmed. In the rightmost hole, etching has stopped halfway after the beginning of etching of the insulating film 1. On the other hand, in the planar structure shown in FIG. 5B, the hole shape is favorable at this stage. This indicates that, with only the etching condition facilitating deposition of the polymer layer 5, hole formation is difficult while the etching rate is low and there is little disturbance in the hole shape. In the low-aspect-ratio hole, the etching rate is lower than in the high-aspect-ratio hole, and the polymer layer 5 is significantly deposited. Hence etch stop is more likely to occur.

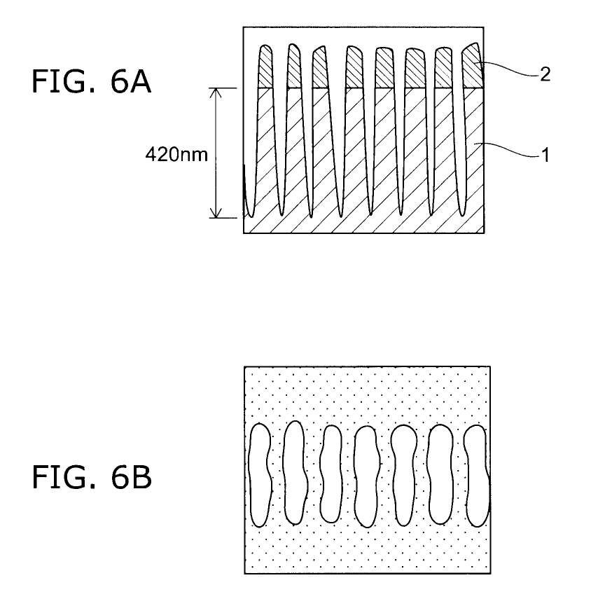

As another comparative example, FIGS. 6A and 6B show structures of high-aspect-ratio holes formed by etching for 70 seconds under the condition for the second etching process alone.

In the cross-sectional structure shown in FIG. 6A, holes are formed in the insulating film 1 having a thickness of 420 nanometers. However, the C film of the mask pattern 2 exhibits bending and flowage. In the planar structure shown in FIG. 6B, disturbance occurs in the hole shape. However, in the case of etching for 52 seconds that does not result in penetration of holes, no bending or flowage of the C film occurs in the state where holes having a depth of 315 nanometers are formed. This example is the result for holes having a short diameter of 56 nanometers, a long diameter of 200 nanometers, and a depth of 420 nanometers. It is noted that, when the second etching process was performed for 70 seconds after the completion of the first etching process, no disturbance occurred in hole diameter. It is considered that this is affected by the progress of deposition of the polymer layer 5 in the first etching process.

As still another comparative example, a description is given of the case where the order of the first etching process and the second etching process is reversed.

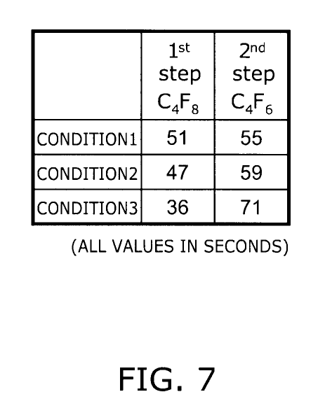

FIG. 7 is a table showing combinations of etching time for the two etching processes in reverse order.

The time of etching performed in the first half using a C₄F₈-based gas was set to 51, 47, and 36 seconds, and the time of etching performed in the second half using a C₄F₆-based gas was set to 55, 59, and 71 seconds.

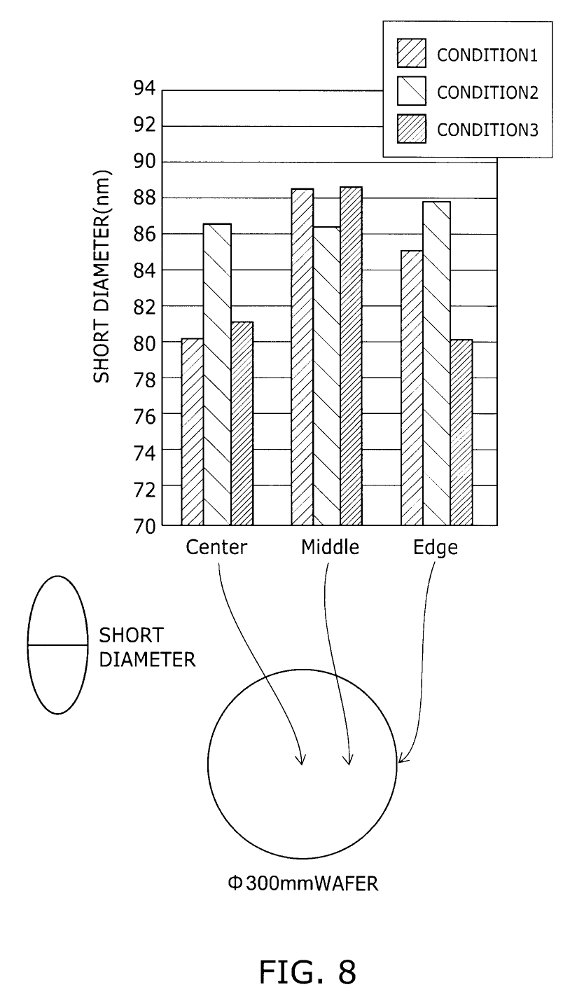

FIG. 8 shows measurements of the short diameter of the high-aspect-ratio hole formed at the center, middle, and edge of a 300-mm diameter wafer.

With regard to the time of etching in the first half using a C₄F₈-based gas, it is confirmed that no disturbance occurs in hole diameter up to 52 seconds. Hence its upper bound was set to 51 seconds so as to avoid disturbance in hole diameter.

The target short diameter is 80 nanometers. However, after the completion of both etching processes, the hole diameter exhibited significant lateral expansion in most conditions, and it was impossible to control the hole diameter simply by changing the etching time.

The embodiment of the invention has been described with reference to the examples. However, the invention is not limited to the above examples. The examples can be appropriately modified without departing from the spirit of the invention. For instance, the combination of the etching gas can be modified from the viewpoint of deposition of the polymer layer 5 and control of the etching rate. Deposition of the polymer layer 5 can be suppressed by addition of hydrogen gas. The etching rate can be increased by addition of a gas that produces a large amount of chemical species such as HF, F, and O by plasma-assisted gas decomposition.

Furthermore, this embodiment is also applicable to finer processing. By way of example, bit lines having a high-aspect-ratio short diameter and source lines having a lower-aspect-ratio width were formed. It was confirmed by SEM observation of the respective holes that a prescribed processing was achieved.

The size of the hole to be formed in the insulating layer decreases with the progress of device downscaling. In this context, the etching process based on a layered mask (e.g., resist film (top film)/SOG (spin-on-glass) film/resist film (bottom film)) known as S-MAP (stacked-mask process) can be used in this embodiment. In this case, the first half of plasma etching is performed using a C₄F₆-based gas while protecting the surface of the mask patterns 2 and 3 and the inner wall of the hole by formation of the polymer layer 5. The second half of etching is performed using a C₄F₈-based gas while suppressing deposition of the polymer layer 5. Thus it is possible to transfer a fine pattern and to simultaneously perform a prescribed processing on high-aspect-ratio and low-aspect-ratio fine holes.

1. A method for manufacturing a semiconductor device in which a first hole and a second hole having a lower aspect ratio than the first hole are formed in an insulating film formed on a semiconductor substrate, the method comprising:
performing a first etching process configured to etch the insulating film; and
performing a second etching process configured to etch the insulating film under a condition that deposition rate of a deposited layer formed on a surface of the insulating film is lower than that in the first etching process.

2. The method for manufacturing a semiconductor device according to claim 1, wherein the first etching process is completed before the first hole reaches a prescribed hole diameter, and the first hole reaches the prescribed hole diameter in the second etching process.

3. The method for manufacturing a semiconductor device according to claim 1, wherein the first etching process is completed before etch stop occurs, and the second hole reaches a prescribed depth in the second etching process.

4. The method for manufacturing a semiconductor device according to claim 1, wherein in the first etching process, the second hole is etched at an etching rate that is 80% or less of the etching rate for the first hole.

5. The method for manufacturing a semiconductor device according to claim 1, wherein the second hole has an aspect ratio that is 0.1 times or less the aspect ratio of the first hole.

6. The method for manufacturing a semiconductor device according to claim 1, wherein a mixed gas containing C₄F₆, oxygen and argon is used as an etching gas in the first etching process.

7. The method for manufacturing a semiconductor device according to claim 1, wherein a mixed gas containing C₄F₈ and oxygen is used as an etching gas in the second etching process.

8. The method for manufacturing a semiconductor device according to claim 7, wherein the mixed gas further contains CH₂F₂.

9. The method for manufacturing a semiconductor device according to claim 7, wherein the mixed gas further contains Co.

10. The method for manufacturing a semiconductor device according to claim 1, wherein the second etching process is performed under a condition that a flow rate of oxygen gas in the second etching process is lower than a flow rate of oxygen gas in the first etching process.

11. The method for manufacturing a semiconductor device according to claim 1, wherein a power of high-frequency electromagnetic wave applied in the first etching process is lower than a power of high-frequency electromagnetic wave applied in the second etching process.

12. The method for manufacturing a semiconductor device according to claim 1, wherein the first hole penetrates through the insulating film in the second etching process.

13. The method for manufacturing a semiconductor device according to claim 1, wherein the second hole penetrates through the insulating film in the second etching process.

14. The method for manufacturing a semiconductor device according to claim 1, wherein the deposited layer is a polymer layer.

15. The method for manufacturing a semiconductor device according to claim 1, wherein the insulating film is made of silicon oxide.

16. A method for manufacturing a semiconductor device in which a first hole and a second hole having a lower aspect ratio than the first hole are formed in an insulating film formed on a semiconductor substrate, the method comprising:
performing a first etching process configured to etch the insulating film; and
performing a second etching process configured to etch the insulating film under a condition that etching rate of the insulating film is higher than that in the first etching process.

17. The method for manufacturing a semiconductor device according to claim 16, wherein a deposition rate of a deposited layer formed on a surface of the insulating film in the second etching process is lower than that in the first etching process.

18. The method for manufacturing a semiconductor device according to claim 16, wherein the first etching process is completed before the first hole reaches a prescribed hole diameter, and the first hole reaches the prescribed hole diameter in the second etching process.

19. The method for manufacturing a semiconductor device according to claim 16, wherein the first etching process is completed before etch stop occurs, and the second hole reaches a prescribed depth in the second etching process.

20. The method for manufacturing a semiconductor device according to claim 16, wherein in the first etching process, the second hole is etched at an etching rate that is 80% or less of the etching rate for the first hole.
